(19) United States
(12) Patent Application Publication
(10) Pub. No.: US 2025/0126753 A1
(43) Pub. Date: Apr. 17, 2025

(54) SERVER MODULE AND SERVER

(71) Applicant: Fulian Precision Electronics (Tianjin) Co., LTD., Tianjin (CN)

(72) Inventor: YA-TING ZHAO, Tianjin (CN)

(21) Appl. No.: 18/898,963

(22) Filed: Sep. 27, 2024

(30) Foreign Application Priority Data
Oct. 17, 2023 (CN) 202311347334.1

(51) Int. Cl. H05K 7/20

(52) U.S. Cl. CPC H05K 7/2039; H05K 7/20154; H05K 7/20709

(57) ABSTRACT

A server module includes a housing, a processor, and a dissipating device. The processor and the dissipating device are disposed in the housing. The dissipating device includes a first fin assembly, a second fin assembly, a third fin assembly, and a substrate. The first fin assembly connects to the processor. The first fin assembly and the second fin assembly are disposed along a first direction. The second fin assembly and the third fin assembly are disposed along a second direction. The thermal conductive member connects the first fin assembly and the second fin assembly. The substrate is disposed between and connected to the second fin assembly and third fin assembly. The second fin assembly, the substrate, and third fin assembly are disposed along the second direction. The present disclosure further provides a server including the server module.

### FIELD

The subject matter herein generally relates to server, and more particularly, to a server module and a server including the server module.

### BACKGROUND

A heat dissipation efficiency of the server affects the performance of the server. If the heat dissipation efficiency of the processor is poor, heat will be accumulated in the sever and deteriorate the performance of the server. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view of an embodiment of a server module according to the present disclosure.

FIG. 2 is a diagrammatic view of the server module of FIG. 1, when a top wall of a housing is removed.

FIG. 3 is a cross-sectional view taken along line III-III of FIG. 1.

FIG. 4 is a diagrammatic view of the server module of FIG. 1, when the top wall is removed.

FIG. 5 is a diagrammatic view of a heat dissipating device of the server module of FIG. 1.

FIG. 6 is a diagrammatic view of the heat dissipating device of the server module of FIG. 1.

FIG. 7 is a diagrammatic view of an embodiment of a server according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

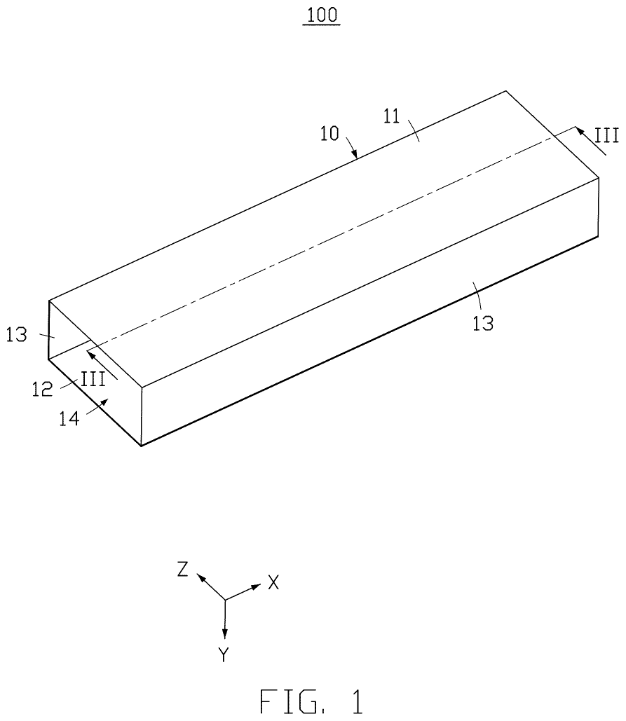

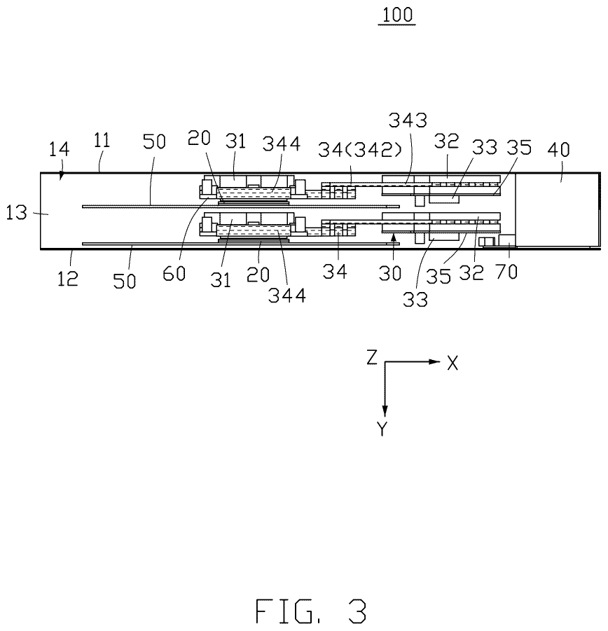

Referring to FIGS. 1, 2, and 3, a server module 100 is provided according to an embodiment of the present disclosure. The server module 100 includes a housing 10, a processor 20, and a heat dissipating device 30. The housing 10 defines a cavity 14, and the processor 20 and the heat dissipating device 30 are disposed in the cavity 14. The heat dissipating device 30 connects to the processor 20. At least a portion of the heat generated by the processor 20 can be transferred to the heat dissipating device 30 and dissipated by the heat dissipating device 30, which is beneficial for the processor 20 to dissipate heat to improve a performance of the server module 100.

In some embodiments, the heat dissipating device 30 includes a first fin assembly 31, a second fin assembly 32, a third fin assembly 33, a thermal conductive member 34, and a substrate 35. The first fin assembly 31 connects to the processor 20. The first fin assembly 31 and the second fin assembly 32 are disposed along a first direction X. The second fin assembly 32 and the third fin assembly 33 are disposed along a second direction Y perpendicular to the first direction X. The thermal conductive member 34 connects the first fin assembly 31 and the second fin assembly 32. The substrate 35 is disposed between and connects the second fin assembly 32 and the third fin assembly 33. The second fin assembly 32, the substrate 35, and the third fin assembly 33 are disposed along the second direction Y.

The first fin assembly 31, the second fin assembly 32, and the third fin assembly 33 can increase a heat dissipation area of the server module 100, thus improving a heat dissipation efficiency of the processor 20. Moreover, the third fin assembly 33 is disposed on a side of the substrate 35 away from the second fin assembly 32, which is beneficial for optimizing airflow resistance, balancing an airflow pressure on both sides of the substrate 35 along the second direction Y, increasing an airflow volume on the second fin assembly 32, improving an heat dissipation effect of the second fin assembly 32, improving the heat dissipation efficiency of the processor 20, and improving the performance of the server module 100. Furthermore, the third fin assembly 33 is further improves the heat dissipation efficiency of the second fin assembly 32, and enhance the heat dissipation efficiency of the processor 20.

If the third fin assembly 33 is omitted, when the airflow flows along the first direction X in the cavity 14, the airflow velocity on the side of the substrate 35 facing away from the second fin assembly 32 is faster, and the airflow velocity on the side of the substrate 35 disposing the second fin assembly 32 is slower. Under an action of airflow pressure, the airflow on one side of the second fin assembly 32 will be reduced, which is not conducive to the heat dissipation efficiency of the second fin assembly 32.

Compared to a comparative example where the third fin assembly 33 is omitted, the present application can reduce the temperature of the processor 20 by 4 degrees Celsius by adding the third fin assembly 33.

By optimizing the airflow resistance in the cavity 14 and balancing the airflow pressure on both sides of the substrate 35 along the second direction Y, the present application has lower requirements on the airflow velocity in the cavity 14, thereby decreasing power consumption.

In some embodiments, the housing 10 includes a top wall 11, a bottom wall 12, and two sidewalls 13. The top wall 11 and the bottom wall 12 are disposed along the second direction Y. The two sidewalls 13 are disposed along a third direction Z. The third direction Z is perpendicular to both the first direction X and the second direction Y. The top wall 11 connects to the two sidewalls 13. The bottom wall 12 connects to the two sidewalls 13. The top wall 11, the bottom wall 12, and the two sidewalls 13 cooperatively form the cavity 14.

In one embodiment, the first fin assembly 31 includes a plurality of first fins. The first fins are made of aluminum.

In one embodiment, the second fin assembly 32 includes a plurality of second fins. The second fins are made of aluminum.

In one embodiment, the third fin assembly 33 includes a plurality of third fins. The third fins are made of aluminum.

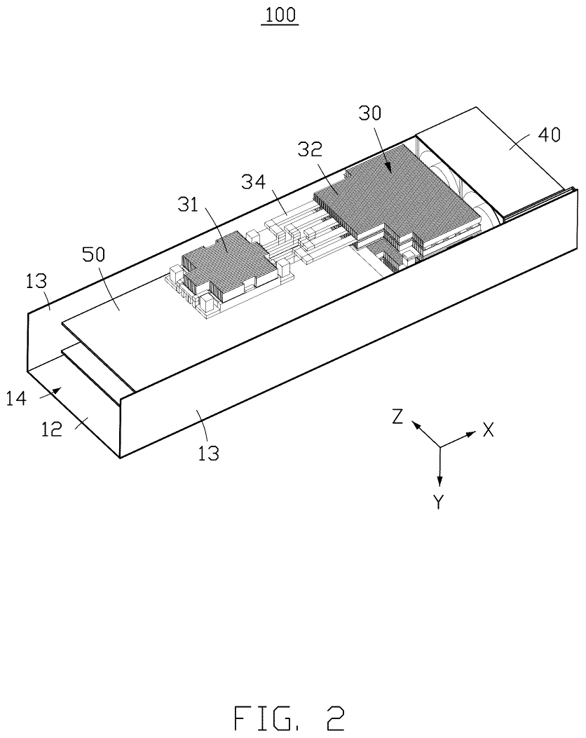

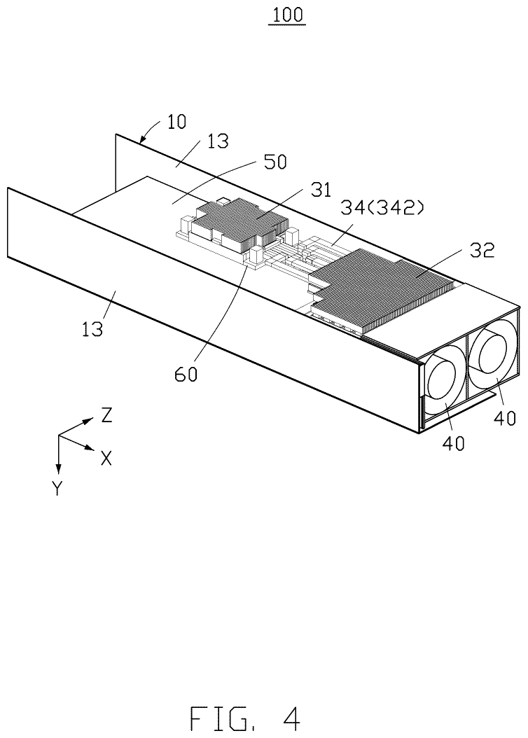

Referring to FIGS. 2, 3, and 4, in some embodiments, the server module 100 further includes a fan 40 connected to the housing 10. The fan 40 can rotate to drive the airflow in the cavity 14 along the first direction X. The airflow can carry away the heat from the first fin assembly 31, the second fin assembly 32, and the third fin assembly 33, thereby improving the heat dissipation efficiency of the processor 20 and enhancing the performance of the server module 100.

When the airflow in the cavity 14 is driven in the first direction X, the airflow sequentially removes the heat from the first fin assembly 31, the heat from the second fin assembly 32, and the heat from the third fin assembly 33, which can reduce an impact of the heat from the second fin assembly 32 and the heat from the third fin assembly 33 on the first fin assembly 31, thereby enhancing the heat dissipation efficiency of the first fin assembly 31, improving the heat dissipation efficiency of the processor 20, and enhancing the performance of the server module 100.

In some embodiments, the heat dissipating device 30 and the fan 40 are disposed along the first direction X. The fan 40 rotates to drive the airflow in the cavity 14 along the first direction X.

In some embodiments, the server module 100 includes a plurality of fans 40 disposed along the second direction Y or the third direction Z, which can increase the airflow velocity in the cavity 14, thereby enhancing the heat dissipation efficiency on the first fin assembly 31, the second fin assembly 32, and the third fin assembly 33.

In some embodiments, the fans 40 are disposed along the third direction Z. (not shown).

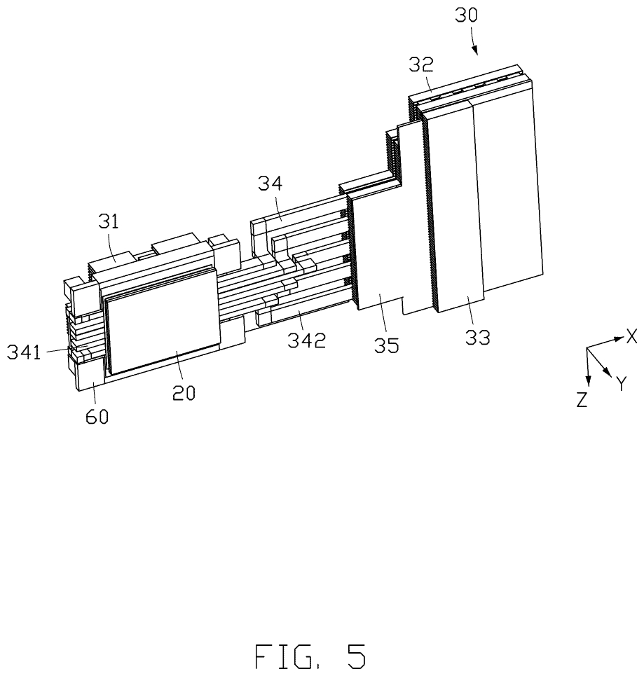

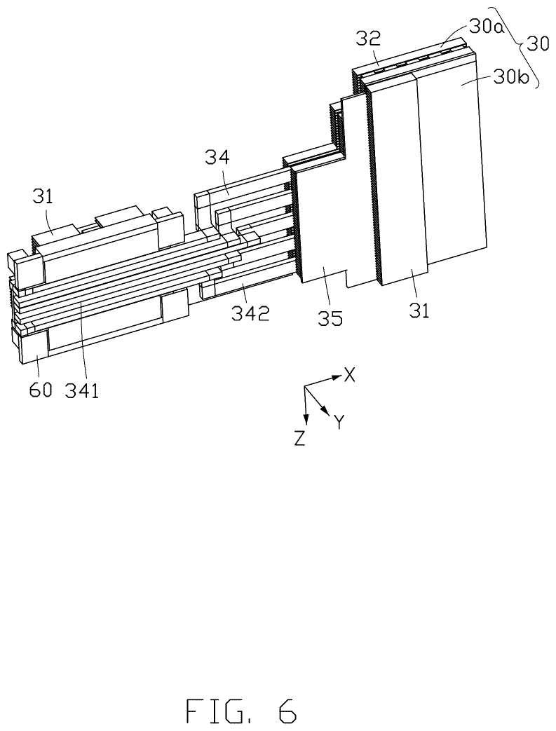

Referring to FIGS. 2, 3, 5, and 6, in some embodiments, the thermal conductive member 34 includes a first portion 341, a second portion 342, and a third portion 343 disposed along the first direction X. The second portion 342 connects the first portion 341 and the third portion 343. The first portion 341 connects to the first fin assembly 31. The third portion 343 connects to the second fin assembly 32. The heat from the first fin assembly 31 is transferred to the first portion 341, the heat from the first portion 341 is transferred to the third portion 343 through the second portion 342, and the heat from the third portion 343 is transferred to the second fin assembly 32, which can improve the heat transformation between the first fin assembly 31 and the second fin assembly 32, thereby enhancing the heat dissipation efficiency of the first fin assembly 31, improving the heat dissipation efficiency of the processor 20, and ultimately improving the performance of the server module 100.

In some embodiments, the third portion 343 is inserted into the second fin assembly 32, which can increase a contact area between the heat conduction member 34 and the second fin assembly 32, thereby improving the heat transfer efficiency between the thermal conductive member 34 and the second fin assembly 32.

In some embodiments, the thermal conductive member 34 is made of copper, which has a high thermal conductivity, thereby facilitating heat transformation and dissipation.

In some embodiments, when the server module 100 is in operation, the processor 20 generates heat, which causes a temperature of the first portion 341 of the thermal conductive member 34 to rise.

The temperature of the first portion 341 is defined as T1, a temperature of the second portion 342 is defined as T2, and a temperature of the third portion 343 is defined as T3. When the server module 100 is in operation, T1>T2>T3.

In some embodiments, the thermal conductive member 34 is hollow, in which a cooling medium 344 is provided. The cooling medium 344 can circulate among the first portion 341, the second portion 342, and the third portion 343, which can enhance heat exchange between the first portion 341 and the third portion 343, thereby enhancing a heat exchange between the first fin assembly 31 and the second fin assembly 32, improving the heat dissipation efficiency of the processor 20 and enhancing the performance of the server module 100.

In some embodiments, a vaporization temperature (that is boiling point) of the cooling medium 344 is defined as T4. When the server module 100 is in operation, T1>T4>T3.

When the server module 100 is in operation, the heat generated by the processor 20 causes the temperature T1 of the first portion 341 to rise. When the temperature T1 exceeds the vaporization temperature T4 of the cooling medium 344, the cooling medium 344 vaporizes, absorbing heat from the first portion 341, which is beneficial for the processor 20 to dissipate heat. Meanwhile, the temperature T3 of the third portion 343 remains below the vaporization temperature T4 of the cooling medium 344, causing the vaporized cooling medium 344 that moves to the third portion 343 to condense back into a liquid state. During the condensation process, the heat in the cooling medium 344 is transferred to the third portion 343, and subsequently, the heat from the third portion 343 is transferred to the second fin assembly 32. The condensed cooling medium 344 from the third portion 343 can then flow back to the first portion 341, creating a circulation of vapor-liquid conversion between the first portion 341 and the third portion 343, thereby enhancing the heat exchange between the first fin assembly 31 and second fin assembly 32, improving the heat dissipation efficiency of the processor 20, and improving the performance of the server module 100.

In some embodiments, the cooling medium 344 can be made of water, alcohol, or a mixture of water and alcohol.

In some embodiments, the server module 100 further includes a circuit board 50 disposed in the cavity 14. The first fin assembly 31 and the processor 20 are disposed on the circuit board 50, and the thermal conductive member 34 connects to the circuit board 50.

In some embodiments, the processor 20 is disposed between the first fin assembly 31 and the circuit board 50. The processor 20, the first fin assembly 31, and the circuit board 50 are disposed along the second direction Y. The heat from the processor 20 can be dissipated by the first fin assembly 31, and some of the heat on the processor 20 can be dissipated by the circuit board 50, which is beneficial for the processor 20 to dissipate heat.

In some embodiments, the server module 100 further includes a structural member 60. The structural member 60 connects the first fin assembly 31 and the thermal conductive member 34, and further connects the circuit board 50. The structural member 60 connects the first fin assembly 31 and the thermal conductive member 34, which can improve a connection stability between the first fin assembly 31 and the circuit board 50, thereby enhancing the shock resistance of the server module 100, and further can improve heat transfer efficiency between the first fin assembly 31 and the circuit board 50, thereby improving the heat dissipation efficiency of the processor 20. The structural member 60 connects the first fin assembly 31 and the thermal conductive member 34, which is improves the heat transfer efficiency between the first fin assembly 31 and the thermal conductive member 34, thereby improving the heat dissipation efficiency of the processor 20.

In some embodiments, the structural member 60 is disposed between the first fin assembly 31 and the circuit board 50. The first fin assembly 31, the structural member 60, and the circuit board 50 are disposed along the second direction Y.

In some embodiments, the structural member 60 is made of aluminum alloy, which can improve heat transfer efficiency between the processor 20 and the first fin assembly 31, thereby improving heat dissipation efficiency, and further can improve strength and rigidity of the structural member 60, thereby reducing a risk of deformation or damage to the structural member 60, and improving the shock resistance of the server module 100.

In some embodiments, the server module 100 further includes a limiting member 70 disposed on the bottom wall 12 and extending in a direction opposite to the second direction Y. The limiting member 70 is connected to the substrate 35. The limiting member 70 can provide support for the substrate 35, enhancing a stability of the substrate 35, the second fin assembly 32, and the third fin assembly 33 in the cavity 14, and thus improving the shock resistance of the server module 100.

In some embodiments, the third fin assembly 33 is disposed between the substrate 35 and the bottom wall 12. The limiting member 70 connects the substrate 35 and the bottom wall 12, such that a space is defined between the substrate 35 and the bottom wall 12 to accommodate the third fin assembly 33, thereby improving the space utilization in the housing 10.

In some embodiments, the server module 100 includes two heat dissipating devices 30, which are defined as a first heat dissipating device 30a and a second heat dissipating device 30b. The first heat dissipating device 30a and a second heat dissipating device 30b are disposed along the second direction Y. The two heat dissipating devices 30 can enhance the heat dissipation efficiency and performance of the server module 100.

In some embodiments, the second fin assembly 32 of the first heat dissipating device 30a connects to the top wall 11, and the substrate 35 of the second heat dissipating device 30b connects to the bottom wall 12 through the limiting member 70, so that the third fin assembly 33 of the first heat dissipating device 30a and the second fin assembly 32 of the second heat dissipating device 30b are spaced apart from each other along the second direction Y to form a channel for air circulation, which is beneficial for heat dissipation.

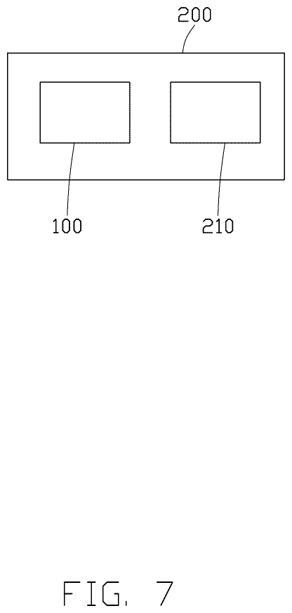

Referring to FIG. 7, a server 200 is provided according to an embodiment of the present disclosure. The server 200 includes the server module 100 and an electronic element 210. The electronic element 210 generates heat during operation, and the server module 100 can dissipate the heat from the electronic element 210.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A server module comprising:
a housing defining a cavity;
a processor disposed in the cavity; and
at least one heat dissipating device disposed in the cavity, each of the at least one heat dissipating device comprising:
a first fin assembly connected to the processor;
a second fin assembly, the first fin assembly and the second fin assembly disposed along a first direction;
a third fin assembly, the second fin assembly and the third fin assembly disposed along a second direction, the second direction perpendicular to the first direction;
a thermal conductive member connected to the first fin assembly and the second fin assembly; and
a substrate disposed between and connected to the second fin assembly and third fin assembly;
wherein the second fin assembly, the substrate, and third fin assembly are disposed along the second direction.

2. The server module of claim 1, further comprising a limiting member, wherein the housing comprises a bottom wall, the limiting member is disposed on the bottom wall and extends in a direction opposite to the second direction, the bottom wall is connected to the substrate, and the third fin assembly is disposed between the substrate and the bottom wall.

3. The server module of claim 2, wherein the housing further comprises a top wall, the top wall and the bottom wall are disposed along the first direction; the at least one heat dissipating device comprises a first heat dissipating device and a second heat dissipating device, the first heat dissipating device and the second heat dissipating device are disposed along the second direction;
the second fin assembly of the first heat dissipating device is connected to the top wall; and
the substrate of the second heat dissipating device is connected to the bottom wall.

4. The server module of claim 1, wherein the thermal conductive member comprises a first portion, a second portion, and a third portion, the second portion is connected to the first portion and the third portion, the first portion is connected to the first fin assembly, the third portion is connected to second fin assembly; and
the thermal conductive member is configured to accommodating and facilitating circulation of a cooling medium among the first portion, the second portion, and the third portion.

5. The server module of claim 4, wherein a temperature of the first portion is defined as T1, a temperature of the second portion is defined as T2, a temperature of the third portion is defined as T3, when the server module is in operation, T1>T2>T3; and
a temperature of the cooling medium is defined as T4, when the server module is in operation, T1>T4>T3.

6. The server module of claim 1, further comprising a circuit board disposed in the cavity, wherein the first fin assembly and the processor are disposed on the circuit board, and the thermal conductive member is connected to the circuit board;
the processor is disposed between the first fin assembly and the circuit board, the processor, the first fin assembly, and the circuit board are disposed along the second direction.

7. The server module of claim 6, further comprising a structural member, wherein the structural member is connected to the first fin assembly, the thermal conductive member, and the circuit board.

8. The server module of claim 1, further comprising at least one fan connected to the housing, wherein the at least one fan is configured to rotate to drive an airflow in the cavity along the first direction.

9. The server module of claim 8, wherein the at least one fan comprises a plurality of fans disposed along the second direction or along a third direction perpendicular to the first direction and the second direction.

10. A server comprising:
an electronic element; and
a server module configured dissipate heat from the electronic element, the server module comprising:
a housing defining a cavity;
a processor disposed in the cavity; and
at least one heat dissipating device disposed in the cavity, each of the at least one heat dissipating device comprising:
a first fin assembly connected to the processor;
a second fin assembly, the first fin assembly and the second fin assembly disposed along a first direction;
a third fin assembly, the second fin assembly and the third fin assembly disposed along a second direction, the second direction perpendicular to the first direction;
a thermal conductive member connected to the first fin assembly and the second fin assembly; and
a substrate disposed between and connected to the second fin assembly and third fin assembly;
wherein the second fin assembly, the substrate, and third fin assembly are disposed along the second direction.

11. The server of claim 10, wherein the server module further comprises a limiting member, the housing comprises a bottom wall, the limiting member is disposed on the bottom wall and extends in a direction opposite to the second direction, the bottom wall is connected to the substrate, and the third fin assembly is disposed between the substrate and the bottom wall.

12. The server of claim 11, wherein the housing further comprises a top wall, the top wall and the bottom wall are disposed along the first direction; the at least one heat dissipating device comprises a first heat dissipating device and a second heat dissipating device, the first heat dissipating device and the second heat dissipating device are disposed along the second direction;
the second fin assembly of the first heat dissipating device is connected to the top wall; and
the substrate of the second heat dissipating device is connected to the bottom wall.

13. The server of claim 10, wherein the thermal conductive member comprises a first portion, a second portion, and a third portion, the second portion is connected to the first portion and the third portion, the first portion is connected to the first fin assembly, the third portion is connected to second fin assembly; and
the thermal conductive member is configured to accommodating and facilitating circulation of a cooling medium among the first portion, the second portion, and the third portion.

14. The server of claim 13, wherein a temperature of the first portion is defined as T1, a temperature of the second portion is defined as T2, a temperature of the third portion is defined as T3, when the server module is in operation, T1>T2>T3; and
a temperature of the cooling medium is defined as T4, when the server module is in operation, T1>T4>T3.

15. The server of claim 10, wherein the server module further comprises a circuit board disposed in the cavity, the first fin assembly and the processor are disposed on the circuit board, and the thermal conductive member is connected to the circuit board;
the processor is disposed between the first fin assembly and the circuit board, the processor, the first fin assembly, and the circuit board are disposed along the second direction.

16. The server of claim 15, wherein the server module further comprises a structural member, the structural member is connected to the first fin assembly, the thermal conductive member, and the circuit board.

17. The server of claim 10, wherein the server module further comprises at least one fan connected to the housing, the at least one fan is configured to rotate to drive an airflow in the cavity along the first direction.

18. The server of claim 17, wherein the at least one fan comprises a plurality of fans disposed along the second direction or along a third direction perpendicular to the first direction and the second direction.
